(19) United States
(12) Patent Application Publication
(10) Pub. No.: US 2025/0204118 A1
(43) Pub. Date: Jun. 19, 2025

(54) SEMICONDUCTOR STRUCTURE

(71) Applicant: ENKRIS SEMICONDUCTOR, INC., Suzhou (CN)

(72) Inventor: Yudong CHENG, Suzhou (CN)

(73) Assignee: ENKRIS SEMICONDUCTOR, INC., Suzhou (CN)

(21) Appl. No.: 18/606,990

(22) Filed: Mar. 15, 2024

(30) Foreign Application Priority Data
Dec. 19, 2023 (CN) 202311753975.7

(51) Int. Cl. H01L 33/64; H01L 33/60

(52) U.S. Cl. CPC H10H 20/8582; H10H 20/856

(57) ABSTRACT

According to embodiments of the present disclosure, a semiconductor structure is provided. The semiconductor structure includes a substrate and a light-emitting structure on the substrate. The light-emitting structure includes a first type semiconductor layer, an active layer and a second type semiconductor layer which are sequentially stacked on the substrate. The first type semiconductor layer includes a first portion not covered by the active layer, and a first heat-dissipation module is disposed on the first portion, so that a surface of the first heat-dissipation module facing the first portion can be used to dissipate heat from the surface of the first portion of the first type semiconductor layer, and a side surface of the first heat-dissipation module facing the light-emitting structure can be used to dissipate heat from the sidewall of the light-emitting structure, thereby increasing heat exchange area and obtaining better heat-dissipation effect.

### CROSS REFERENCE TO RELATED APPLICATIONS

This application claims priority to Chinese Patent Application No. 2023117539757 entitled “SEMICONDUCTOR STRUCTURE” filed on Dec. 19, 2023, the entire content of which is incorporated herein by reference.

### TECHNICAL FIELD

The present disclosure relates to the technical field of semiconductors and in particular, to semiconductor structures.

### BACKGROUND

With the development of display technology, light-emitting devices, such as Light-emitting diodes (LED), Organic light-emitting diode (OLED), and Liquid crystal displays (LCD), are widely used in electronic products, such as computers, televisions, mobile phones and wearable devices. The Micro Light-emitting diode (Micro LED) is an emerging technology mainly based on inorganic GaN-based LEDs. Compared the Micro LED with the LCD and the OLED, the Micro LED has advantages, such as small size, high contrast ratio, low power consumption and long service life, etc. However, the current photoelectric conversion efficiency of the Micro LED light-emitting devices needs to be improved. A large proportion of electrical energy is converted into thermal energy, resulting in excessively high temperature in the light-emitting device, thereby reducing the service life of the light-emitting device. Therefore, a heat-dissipation problem of the light-emitting devices has become a major issue affecting the development and the application thereof.

### SUMMARY

In view of this, the present disclosure provides a semiconductor structure to solve a problem of poor heat-dissipation of a light-emitting structure.

According to one aspect of the present disclosure, the present disclosure provides a semiconductor structure which includes: a substrate; a light-emitting structure on the substrate; where the light-emitting structure includes first type semiconductor layer, an active layer and a second type semiconductor layer which are sequentially stacked on the substrate, and the first type semiconductor layer includes a first portion not covered by the active layer; and a first heat-dissipation module on the first portion.

### BRIEF DESCRIPTION OF DRAWINGS

FIG. 1 is a schematic diagram of a top view of a semiconductor structure according to an embodiment of the present disclosure.

FIG. 2 is a schematic diagram of a section along line AB in FIG. 1.

FIG. 3 is a schematic diagram of a section along line CD in FIG. 1.

FIG. 4 is a schematic diagram of a top view of another semiconductor structure according to an embodiment of the present disclosure.

FIG. 5 is a schematic diagram of a section of a semiconductor structure according to an embodiment of the present disclosure.

FIG. 6 is a schematic diagram of a section of another semiconductor structure according to an embodiment of the present disclosure.

FIG. 7 is a schematic diagram of a section of another semiconductor structure according to an embodiment of the present disclosure.

FIG. 8 is a schematic diagram of a section of another semiconductor structure according to an embodiment of the present disclosure.

FIG. 9 is a schematic diagram of a top view of another semiconductor structure according to an embodiment of the present disclosure.

FIG. 10 is a schematic diagram of a top view of another semiconductor structure according to an embodiment of the present disclosure.

FIG. 11 is a schematic diagram of a section of another semiconductor structure according to an embodiment of the present disclosure.

FIG. 12 is a schematic diagram of a section of another semiconductor structure according to an embodiment of the present disclosure.

FIG. 13 is a schematic diagram of a top view of another semiconductor structure according to an embodiment of the present disclosure.

FIG. 14 is a schematic diagram of a top view of another semiconductor structure according to an embodiment of the present disclosure.

FIG. 15 is a schematic diagram of a section along the line EF in FIG. 14.

### REFERENCE SIGNS

10—Substrate; 20—Light-emitting structure; 21—First type semiconductor layer; 211—First portion; 212—Protrusion; 22—Active layer; 23—Second type semiconductor layer; 30—First heat-dissipation module; 31—First heat-dissipation sub-module; 32—Second heat-dissipation sub-module; 33—Conductive layer; 331—First conductive structure; 332—Second conductive structure; 333—Third conductive structure; 334—Fourth conductive structure; 40—Dielectric layer; 41—First through-hole; 42—Second through-hole; 51—First electrode; 52—Second electrode; 60—Second heat-dissipation module.

### DETAILED DESCRIPTION

To enable those in the art to better understand the solution of the present disclosure, the technical solutions in embodiments of the present disclosure will be clearly and completely described below in conjunction with the accompanying drawings in embodiments of the present disclosure. Obviously, the described embodiments are part of embodiments of the present disclosure, but not all of the embodiments. It should be understood that, the terms first, second, etc. used in the present disclosure are only used to distinguish the same type of information from each other but are not necessarily used to describe a specific order or sequence.

The present disclosure provides a semiconductor structure that can solve the problem of poor heat-dissipation of light-emitting devices and contributes to improving the performance of the semiconductor structure.

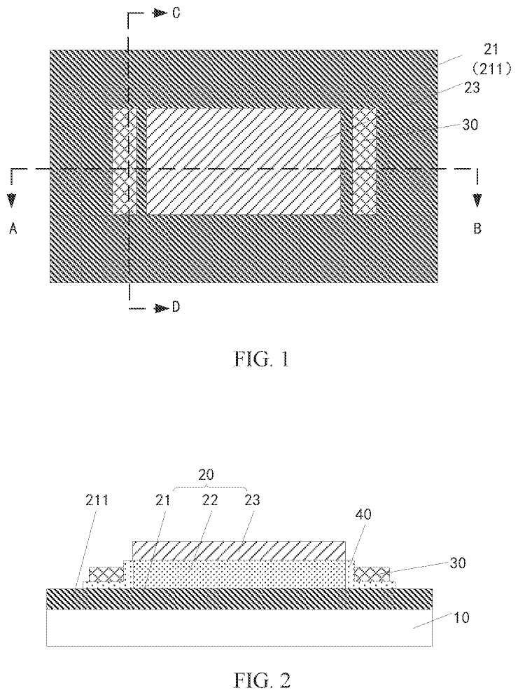

FIG. 1 is a schematic diagram of a top view of a semiconductor structure according to an embodiment of the present disclosure. FIG. 2 is a schematic diagram of a section along line AB in FIG. 1. As shown in FIGS. 1 and 2, a semiconductor structure according to an embodiment of the present disclosure includes a substrate 10, a light-emitting structure 20 and a first heat-dissipation module 30.

Specifically, as shown in FIGS. 1 and 2, the light-emitting structure 20 is on the substrate 10, where the light-emitting structure 20 includes a first type semiconductor layer 21, an active layer 22 and a second type semiconductor layer 23 which are sequentially stacked on the substrate 10, and the first type semiconductor layer 21 includes a first portion 211 not covered by the active layer 22 and a second portion covered by the active layer 22. The first heat-dissipation module 30 is on the first portion 211.

Specifically, the first heat-dissipation module 30 may be a thermoelectric material heat-dissipation device, and the thermoelectric material heat-dissipation device can contribute to cooling and the heat-dissipation of the device. The first heat-dissipation module 30 is on the first portion 211, for example, the first heat-dissipation module 30 is on the first portion 211 and close to at least part of sidewalls of the active layer 22, in other words, the first heat-dissipation module 30 and the active layer 22 are disposed on the first type semiconductor layer 21 side by side. In some embodiments, the first heat-dissipation module 30 may be bonded to the top surface the first portion 211 after being prepared in advance. The surface of the first heat-dissipation module 30 may include an insulation layer to avoid affecting the circuit layout in the semiconductor structure.

In this embodiment, by disposing the first heat-dissipation module 30 on the first portion 211, the heat exchange area between the first heat-dissipation module 30 and the light-emitting structure 20 can be larger. The surface of the first heat-dissipation module 30 facing the substrate 10 can be used to dissipate heat from the surface for the first portion 211 of the first type semiconductor layer 21, and the side surface of the first heat-dissipation module 30 facing the active layer 22 of the light-emitting structure 20 can be used to dissipate heat from the sidewalls of the light-emitting structure 20. Therefore, the heat-dissipation efficiency of the light-emitting structure 20 is high and the heat-dissipation effect is very good.

In addition, disposing the first heat-dissipation module 30 on the first portion 211 can further save space. Specifically, the size of the first heat-dissipation module 30 is smaller than the size of the light-emitting structure 20. An orthographic projection of the first heat-dissipation module 30 on the substrate is in an orthographic projection of the first portion 211 of the first type semiconductor layer 21 on the substrate. The first portion 211 is often used to dispose the electrode structure of the first type semiconductor layer 21, so that disposing the first heat-dissipation module 30 at part of the space on the first portion 211 makes it easier to integrate the first heat-dissipation module 30 and the light-emitting structure 20 together, thereby the heat-dissipation of the light-emitting structure 20 is achieved without increasing the volume of the semiconductor structure.

In some embodiments, as shown in FIGS. 1 and 2, the top view of the active layer 22 is rectangular in shape, and two first heat-dissipation modules 30 are respectively disposed at two sidewalls of the active layer 22, which can reduce the volume of the semiconductor structure. In some embodiments, the four side walls of the rectangular active layer 22 in the top view can each be provided with a first heat-dissipation module, that is, there are a total of four first heat-dissipation modules, which can maximize the heat conduction area between the first heat-dissipation module 30 and the light-emitting structure 20, thereby improving the heat-dissipation efficiency for the light-emitting structure 20. The number and shape of the first heat-dissipation modules 30 can be adjusted according to the requirements of the semiconductor structure, for example, one first heat-dissipation module can be provided on one of the sidewalls of the active layer 22 with a rectangular shape in the top view.

In some embodiments, a material of the substrate 10 may be sapphire, silicon carbide, silicon, or diamond.

Specifically, the light-emitting structure 20 in an embodiment of the present disclosure may be a Micro LED. The first type semiconductor layer 21 may be an N-type semiconductor layer, and materials of the first type semiconductor layer 21 may be N-type doped Group III nitride-based materials. The N-type doping element may include at least one of Si, Ge, Sn, Se or Te. The active layer 22 may be at least one of a single quantum well structure, a multiple quantum well structure, a quantum line structure or a quantum dot structure. The second type semiconductor layer 23 may be a P-type semiconductor layer, and materials of the second type semiconductor layer 23 may be P-type doped Group III nitride-based materials. The P-type doping element may be at least one of Mg, Zn, Ca, Sr or Ba. The group III nitride material may include any one or any combination of GaN, AlGaN, InGaN and AlInGaN.

In some embodiments, the light-emitting structure 20 may further include a transparent electrode disposed at a side of the second type semiconductor layer 23 away from the substrate 10. The material of the transparent electrode may be transparent conductive materials including indium zinc oxide (IZO), indium tin oxide (ITO), zinc tin oxide (ZTO), etc.

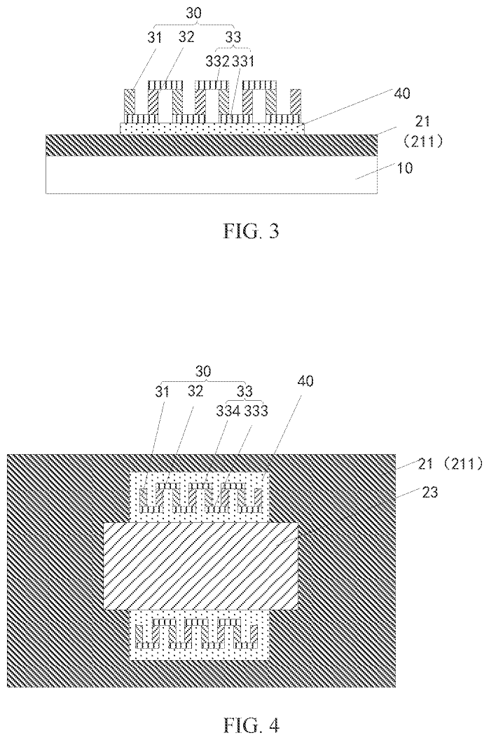

FIG. 3 is a schematic diagram of a section along line CD in FIG. 1. As shown in FIG. 3, in a direction parallel to the substrate 10 and along a sidewall of the active layer 22, the first heat-dissipation module 30 includes first heat-dissipation sub-modules 31 and second heat-dissipation sub-modules 32 which are arranged alternately, and a conductive layer 33 that connects the first heat-dissipation sub-modules 31 and the second heat-dissipation sub-modules 32 in series, so that a structure electrically connected in series and thermally connected in parallel is formed. The first heat-dissipation sub-modules 31 are made of P-type semiconductor thermoelectric materials, and the second heat-dissipation sub-modules 32 are made of N-type semiconductor thermoelectric materials. In some embodiments of the present disclosure, materials of the conductive layer are light reflective materials.

In other words, the first heat-dissipation module 30 may include a P-type thermoelectric material and an N-type thermoelectric material, where the P-type thermoelectric material and the N-type thermoelectric material are connected electrically in series and thermally in parallel, which is a heat-dissipation device that actively dissipates heat. The N-type thermoelectric materials refer to semiconductor thermoelectric materials which carriers are electrons, for example, N-type thermoelectric materials may be Bi2Te3-based, PbX-based (X=S, Se, Te), silicon-based, magnesium-based materials, etc., but which are not limited to the listed materials. The P-type thermoelectric materials refer to semiconductor thermoelectric materials, in which carriers are holes, including Bi2Te3-based, Sb2Te3-based, SnTe-based, PbTe-based, FeSi2-based, etc., but which are not limited to the listed materials.

It should be noted that, an arrangement direction of the first heat-dissipation sub-modules 31 and the second heat-dissipation sub-modules 32 is along the sidewall of the adjacent active layer 22.

For example, as shown in FIG. 3, in an embodiment of the present disclosure, the conductive layer 33 includes a plurality of first conductive structures 331 disposed apart and a plurality of second conductive structures 332 disposed apart. The first conductive structures 331 are disposed at a side of the first heat-dissipation sub-modules 31 and the second heat-dissipation sub-modules 32 facing the substrate 10 (close to the substrate 10). The second conductive structures 332 are disposed at a side of the first heat-dissipation sub-modules 31 and the second heat-dissipation sub-modules 32 away from the substrate 10. The first heat-dissipation module 30 is formed by a plurality of groups connected in series, and each group includes the first heat-dissipation sub-module 31, the first conductive structure 331, the second heat-dissipation sub-module 32 and the second conductive structure 332 which are connected in series.

Specifically, as shown in FIG. 3, in a direction perpendicular to the substrate 10, the second conductive structure 332 is at a side of the first conductive structure 331 away from the substrate 10. The first conductive structure 331 and the second conductive structure 332 are respectively at two sides of the first heat-dissipation sub-module 31 which are opposite. The first conductive structure 331 and another second conductive structure 332 are respectively at two sides of the second heat-dissipation sub-module 32 which are opposite. In a direction parallel to the substrate 10, a plurality of first conductive structures 331 are disposed apart, and a plurality of second conductive structures 332 are disposed apart, so that the minimum repeating unit of the first heat-dissipation module 30 includes the first heat-dissipation sub-module 31, the first conductive structure 331, the second heat-dissipation sub-module 32 and the second conductive structure 332, the minimum repeating unit is a group, and a plurality of groups are connected in series to form an electrical series structure, thereby achieving the heat-dissipation function.

It should be noted that, as shown in FIG. 3, within a group, an end of the first heat-dissipation sub-module 31 close to the substrate 10 is electrically connected to an end of the second heat-dissipation sub-module 32 close to the substrate 10 through the first conductive structure 331, an end of the first heat-dissipation sub-module 31 away from the substrate 10 and an end of the second heat-dissipation sub-module 32 are not electrically connected. Within two adjacent groups, such as the first group and the second group, the second heat-dissipation sub-module 32 in the first group and the first heat-dissipation sub-modules 31 in the second group are electrically connected through the second conductive structure 332 in the first group.

It should be noted that, in a first heat-dissipation module 30, the heat-dissipation function is achieved by respectively providing electrical signals to the first heat-dissipation sub-module 31 and the second heat-dissipation sub-module 32 at both ends thereof.

FIG. 4 is a schematic diagram of a top view of another semiconductor structure according to an embodiment of the present disclosure. As shown in FIG. 4, in an embodiment of the present disclosure, the conductive layer 33 includes a plurality of third conductive structures 333 disposed apart and a plurality of fourth conductive structures 334 disposed apart. The third conductive structures 333 are disposed at a side of the first heat-dissipation sub-modules 31 and the second heat-dissipation sub-modules 32 facing the active layer 22 (close to the active layer 22). The fourth conductive structures 334 are disposed at a side of the first heat-dissipation sub-modules 31 and the second heat-dissipation sub-modules 32 away from the active layer 22. The first heat-dissipation module 30 is formed by a plurality of groups connected in series, and each group includes the first heat-dissipation sub-module 31, the third conductive structure 333, the second heat-dissipation sub-module 32 and the fourth conductive structure 334 which are connected in series.

Specifically, as shown in FIG. 4, in a direction parallel to the substrate 10 and along a direction from the active layer 22 pointing to the first heat-dissipation module 30, the fourth conductive structure 334 is at a side of the third conductive structure 333 away from the active layer 22. The third conductive structure 333 and the fourth conductive structure 334 are respectively at two sides of the first heat-dissipation sub-module 31 which are opposite. The third conductive structure 333 and another fourth conductive structure 334 are respectively at two sides of the second heat-dissipation sub-module 32 which are opposite. In a direction parallel to the substrate 10 and along the sidewalls of the active layer 22, the plurality of third conductive structures 333 are disposed apart, and the plurality of fourth conductive structures 334 are disposed apart, so that the minimum repeating unit of the first heat-dissipation module 30 includes the first heat-dissipation sub-module 31, the third conductive structure 333, the second heat-dissipation sub-module 32 and the fourth conductive structure 334, the minimum repeating unit is a group, and the plurality of groups are connected in series to form an electrical series structure, thereby achieving the heat-dissipation function.

It should be noted that, as shown in FIGS. 3 and 4, the gaps between the first heat-dissipation sub-module 31, the second heat-dissipation sub-module 32 and the conductive layer 33 may be filled with the insulation material.

In an embodiment of the present disclosure, the material of the conductive layer 33 may be light reflective materials, for example, the material of the conductive layer 33 may be silver, and the third conductive structure 333 and/or the fourth conductive structure 334 may form a grating to achieve the modification of the light transmission. For example, in the direction perpendicular to the substrate 10, the thicknesses of the third conductive structure 333 and the fourth conductive structure 334 are greater than or equal to the thickness of the active layer 22, and the conductive layer 33 forms a grating surrounding the active layer 22, reflecting the light emitted from the sidewall of the active layer 22. Therefore, the light loss from the side of the active layer 22 is decreased, and the light-emitting efficiency of the light emitted from the second type semiconductor layer along the direction away from the substrate is improved. In addition, the existence of the grating can further realize the adjustment of the polarization state, for example, the third conductive structure 333 or the fourth conductive structure 334 form the grating, and the third conductive structure 333 or the fourth conductive structure 334 with different sizes and different spacing distances can resolve and manipulate the light to adjust the polarization state. In an embodiment of the present disclosure, the conductive layer 33 in the first heat-dissipation module 30 is used as the grating, which can save the process flow of forming the grating layer and further reduce the volume of the semiconductor structure. Therefore, this structure can reduce the production cost of the semiconductor structure.

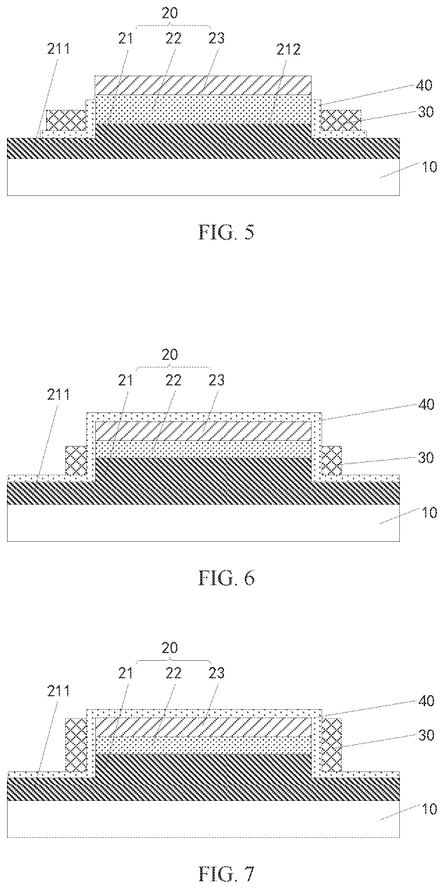

FIG. 5 is a schematic diagram of a section of a semiconductor structure according to an embodiment of the present disclosure. As shown in FIG. 5, in order to further improve the heat-dissipation efficiency, the first type semiconductor layer 21 in the semiconductor structure provided by an embodiment of the present disclosure includes a protrusion 212 higher than the first portion 211 and covered by the active layer 22, and the first heat-dissipation module 30 is disposed at the junction of the first portion 211 and the protrusion 212, for example, a step portion formed by the first portion 211 and the protrusion 212. Since the heat generated during the operation of the light-emitting structure 20 is easy to accumulate at the first type semiconductor layer 21, the first type semiconductor layer 21 is disposed into a stepped shape including the first portion 211 and the protrusion 212, and the first heat-dissipation module 30 is disposed at the junction of the first portion 211 and the protrusion 212, which can enable a surface of the first heat-dissipation module 30 facing the substrate 10 to dissipate heat from the first portion 211 of the first type semiconductor layer 21, and a surface of the first heat-dissipation module 30 facing the protrusion 212 is used to dissipate heat from the protrusion 212 of the first type semiconductor layer 21. In such a structure, the first heat-dissipation module 30 has a larger heat conduction area for the first type semiconductor layer 21 where heat is concentrated, which can improve the heat-dissipation efficiency of the first type semiconductor layer 21 through the first heat-dissipation module 30, thereby effectively reducing the temperature of the light-emitting structure 20.

FIG. 6 is a schematic diagram of a section of another semiconductor structure according to an embodiment of the present disclosure. As shown in FIG. 6, the semiconductor structure of an embodiment of the present disclosure further includes a dielectric layer 40. Specifically, the dielectric layer 40 is between the light-emitting structure 20 and the first heat-dissipation module 30, so that the first heat-dissipation module 30 is electrically isolated from the light-emitting structure 20. By disposing the dielectric layer 40 between the light-emitting structure 20 and the first heat-dissipation module 30, the electrical connection between the first heat-dissipation module 30 and the light-emitting structure 20 can be avoided, and circuit failure of the light-emitting structure 20 or the first heat-dissipation module 30 can be avoided, thereby improving the reliability of the semiconductor structure. The first heat-dissipation module 30 connects a part of the surface of the dielectric layer 40, so that the heat of the light-emitting structure 20 is first conducted to the dielectric layer 40 and then to the first heat-dissipation module 30. According to the embodiment of the present disclosure, heat of the light-emitting structure 20 is dissipated through the first heat-dissipation module 30, which can reduce the temperature of the light-emitting structure 20.

Alternatively, the dielectric layer 40 may be an insulation material. For example, the dielectric layer 40 may be silicon dioxide, silicon nitride, silicon carbide, etc.

In some embodiments, the dielectric layer 40 may include a distributed Bragg reflector (DBR) structure. Specifically, the DBR structure is composed of two kinds of layers with different refractive indexes which are alternatively stacked. The dielectric layer 40 not only plays an insulation role, but also plays a role in reflecting light, which can improve the reflection effect of the emitted light of the light-emitting structure 20, thereby increasing the luminous intensity of the emitted light.

FIG. 7 is a schematic diagram of a section of another semiconductor structure according to an embodiment of the present disclosure. As shown in FIG. 7, in the semiconductor structure according to an embodiment of the present disclosure, the surface of the first heat-dissipation module 30 away from the substrate 10 is higher than the surface of the active layer 22 away from the substrate 10. In other words, the sidewalls of the first heat-dissipation module 30 can surround the active layer 22, and the heat generated by the active layer 22 during operation can be transferred to the first heat-dissipation module 30 through thermal conduction. Therefore, this structure further increases the heat exchange area between the light-emitting structure 20 and the first heat-dissipation module 30 and increases the heat-dissipation area of the first heat-dissipation module 30 for the light-emitting structure 20. For example, the surface of the first heat-dissipation module 30 away from the substrate 10 may be substantially flush with the surface of the second type semiconductor layer 23 away from the substrate 10, which can further improve the heat exchange area between the light-emitting structure 20 and the first heat-dissipation module 30.

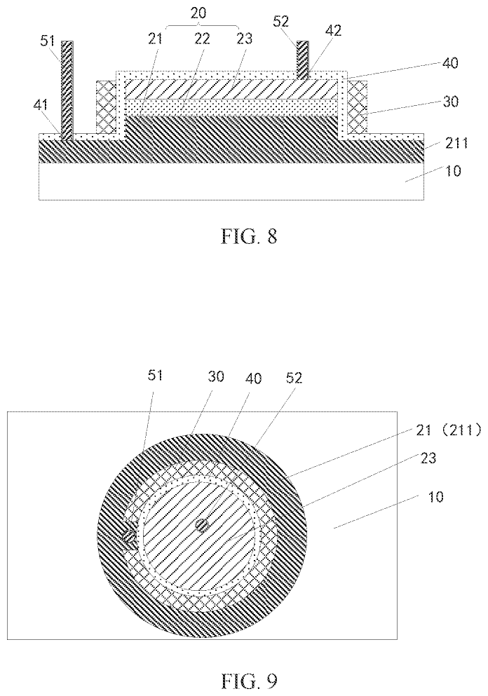

FIG. 8 is a schematic diagram of a section of another semiconductor structure according to an embodiment of the present disclosure. As shown in FIG. 8, the semiconductor structure according to an embodiment of the present disclosure further includes a first electrode 51 and a second electrode 52, and the dielectric layer 40 further covers the sidewalls of the light-emitting structure 20 and the surface of the light-emitting structure 20 away from the substrate 10. The first electrode 51 is electrically connected to the first type semiconductor layer 21 through a first through-hole 41 which is in the dielectric layer 40 on the first portion 211, and the first electrode 51 is used for providing electrical signals for the first type semiconductor layer 21. The second electrode 52 is electrically connected to the second type semiconductor layer 23 through a second through-hole 42 which is in the dielectric layer 40 on the second type semiconductor layer 23, and the second electrode 52 is used for providing electrical signals for the second type semiconductor layer 23. In other words, the orthographic projection of the second electrode 52 on the substrate 10 is in the orthographic projection of the second type semiconductor layer 23 on the substrate 10. In some embodiments, the materials of the first electrode 51 and the second electrode 52 may be metal materials respectively, for example, the materials of the first electrode 51 and the second electrode 52 may be copper, silver, iron and alloys thereof respectively. In some embodiments, the sidewalls of the first electrode 51 and the second electrode 52 are covered with an insulation layer (not labelled) to avoid short circuit.

In some embodiments, in a direction parallel to the substrate 10, the first heat-dissipation module 30 surrounds a circumference formed by the sidewalls of the active layer 22; or the first heat-dissipation module 30 surrounds a part of the sidewalls of the active layer 22.

Specifically, FIG. 9 is a schematic diagram of a top view of another semiconductor structure according to an embodiment of the present disclosure, and as shown in FIG. 9, in the semiconductor structure according to an embodiment of the present disclosure, in the direction parallel to the substrate 10, where the first heat-dissipation module 30 surrounds a part of the sidewalls of the active layer 22, the orthographic projection of the first heat-dissipation module 30 on the substrate 10 is an annular with a gap, and at least a part of the orthographic projection of the first electrode 51 on the substrate 10 is disposed in the gap, saving the space of the first portion 211.

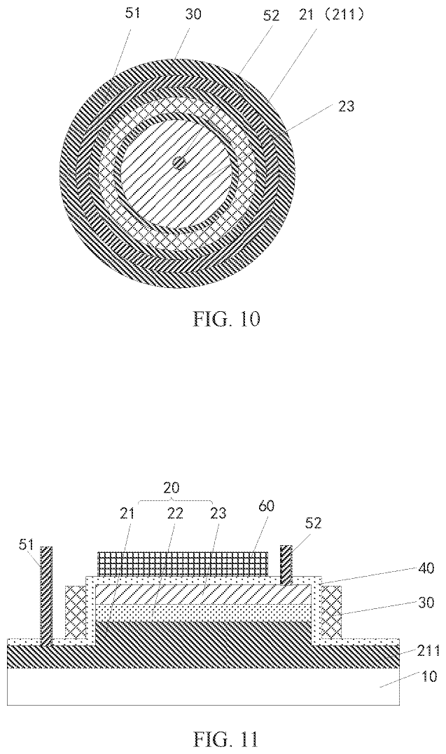

Specifically, FIG. 10 is a schematic diagram of a top view of another semiconductor structure according to an embodiment of the present disclosure, and as shown in FIG. 10, in the semiconductor structure according to an embodiment of the present disclosure, in a direction parallel to the substrate 10, where the first heat-dissipation module 30 surrounds a circumference formed by the sidewalls of the active layer 22, the first electrode 51 is disposed at the side of the first heat-dissipation module 30 away from the active layer 22. Specifically, compared with the semiconductor structure with the first electrode 51 disposed between the active layer 22 and the first heat-dissipation module 30, in the semiconductor structure with the first heat-dissipation module 30 disposed between the active layer 22 and the first electrode 51, the first heat-dissipation module 30 can not only cool down the light-emitting structure 20 but also dissipate heat for the first electrode 51 to some degree, thereby improving the heat-dissipation efficiency. In addition, the first electrode 51 is arranged in an annular shape surrounding the active layer 22 and the second type semiconductor layer 23. The first electrode 51 may reflect the light reaching the first electrode 51, which can reach the effect of concentrating the light and avoiding the light from being transmitted to the non-display surface. Therefore, the luminous efficiency of the light-emitting structure 20 is improved. It should be noted that, the first electrode 51 and the first heat-dissipation module 30 are electrically isolated. The description “the first electrode 51 surrounds the first dissipation module 30” in the embodiment of the present disclosure may involve that there is physical contact between the first electrode 51 and the first heat-dissipation module 30, or may involve that there is a certain distance between the first electrode 51 and the first heat-dissipation module 30.

In some embodiments, as shown in FIGS. 9 and 10, the orthographic projection of the second type semiconductor layer 23 and the active layer 22 on the substrate 10 is circular, which can improve the uniformity of light emitted toward all directions and avoid the chromatic aberration. In some embodiments, the orthographic projections of the second type semiconductor layer 23 and the active layer 22 on the substrate 10 are a triangle, a quadrilateral or other shapes respectively.

FIG. 11 is a schematic diagram of a section of another semiconductor structure according to an embodiment of the present disclosure. As shown in FIG. 11, the semiconductor structure according to an embodiment of the present disclosure further includes a second heat-dissipation module 60. The second heat-dissipation module 60 is on a surface of the light-emitting structure 20 away from the substrate 10. The second heat-dissipation module 60 is disposed on the surface of the light-emitting structure 20 away from the substrate 10, so that the heat of the second type semiconductor layer 23 can be transferred to the second heat-dissipation module 60. The second type semiconductor layer 23 is also an area with higher heat in the light-emitting structure 20. According to the embodiment of the present disclosure, the second heat-dissipation module 60 is provided, which can further improve the heat-dissipation effect for the light-emitting structure 20 and reduce the temperature of the light-emitting structure 20, thereby extending the service life of the light-emitting structure 20.

FIG. 12 is a schematic diagram of a section of another semiconductor structure according to an embodiment of the present disclosure. Specifically, as shown in FIG. 12, in the direction parallel to the substrate 10, the second heat-dissipation module 60 includes: a plurality of third heat-dissipation sub-modules 35 and a plurality of fourth heat-dissipation sub-modules 36 which are disposed alternately, and a plurality of fifth conductive structures 335 spaced apart and a plurality of sixth conductive structures 336 spaced apart. The third heat-dissipation sub-module 35 is made of P-type semiconductor thermoelectric material, and the fourth heat-dissipation sub-module 36 is made of N-type semiconductor thermoelectric material. The five conductive structures 335 are disposed at the side of the third heat-dissipation sub-module 35 and the fourth heat-dissipation sub-module 36 facing the substrate 10, and the sixth conductive structures 336 are disposed at the side of the third heat-dissipation sub-module 35 and the fourth heat-dissipation sub-module 36 away from the substrate 10. The second heat-dissipation module 60 is formed by a plurality of groups connected in series, each group includes the third heat-dissipation sub-module 35, the fifth conductive structure 335, the fourth heat-dissipation sub-module 36 and the sixth conductive structure 336 which are connected in series.

Similar to the first heat-dissipation module 30, the fifth conductive structure 335 and the sixth conductive structure 336 in the second heat-dissipation module 60 may be further used as a grating, and at this case, the light-emitting direction of the light-emitting structure 20 is a direction from the active layer 22 pointing to the substrate 10.

In some embodiments, the light-emitting direction of the light-emitting structure 20 is the direction from the active layer 22 pointing to the second type semiconductor layer 23, and the second heat-dissipation module 60 is disposed at the outer periphery of the second type semiconductor layer 23 to avoid affecting the luminous efficiency.

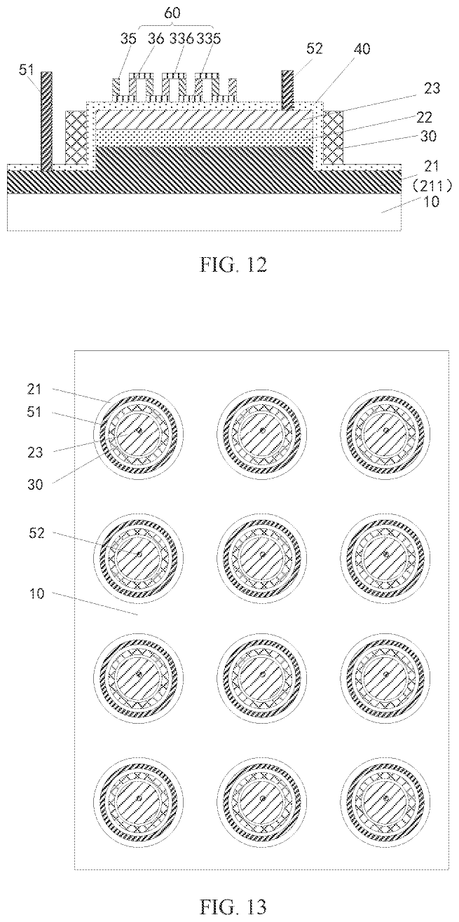

FIG. 13 is a schematic diagram of a top view of a semiconductor structure according to an embodiment of the present disclosure. As shown in FIG. 13, a semiconductor structure according to an embodiment of the present disclosure includes a plurality of light-emitting structures 20, and the plurality of light-emitting structures 20 are disposed in an array on the substrate 10. In other words, the semiconductor structure in this embodiment may be used to form a display panel, and the multiple light-emitting structures 20 can be used to form pixels in the display panel. The light-emitting structures 20 may include multiple light-emitting colors, and the arrangement of the light-emitting structures 20 may be diamond shaped, delta shaped, etc.

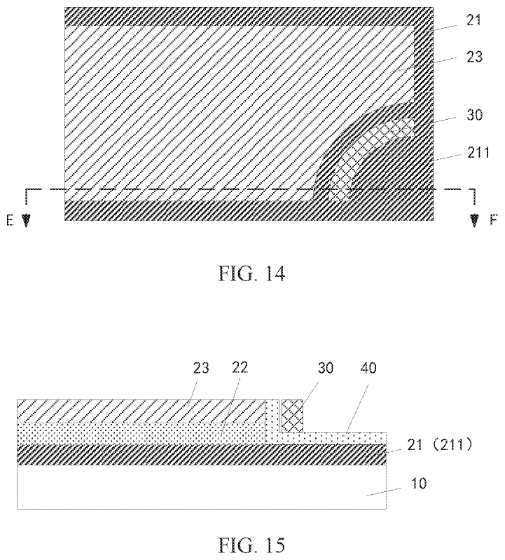

FIG. 14 is a schematic diagram of a top view of another semiconductor structure according to an embodiment of the present disclosure. FIG. 15 is a schematic diagram of a section along the line EF in FIG. 14. In some embodiments, as shown in FIGS. 14 and 15, one light-emitting structure 20 corresponds to one first heat-dissipation module 30, the active layer 22 and the second type semiconductor layer 23 of the light-emitting structure 20 have a notch that exposes the first type semiconductor layer 21, and the notch is the first portion 211 of the first type semiconductor layer 21. The first heat-dissipation module 30 is disposed on the first portion 211, and the remaining part of the notch except the first heat-dissipation module 30 may be used to dispose the first electrode (not shown in the drawings), saving the space in the semiconductor structure. It should be noted that, for clarity of drawing, FIG. 14 does not illustrate the dielectric layer 40 between the light-emitting structure 20 and the first heat-dissipation module 30. FIG. 15 illustrates the dielectric layer 40 between the light-emitting structure 20 and the first heat-dissipation module 30.

In the embodiments of the present disclosure, by disposing the first heat-dissipation module at the first portion, the surface of the first heat-dissipation module facing the substrate can be used to dissipate heat from the surface for the first portion of the first type semiconductor layer, and the side surface of the first heat-dissipation module facing the active layer of the light-emitting structure can be used to dissipate heat from the sidewalls of the light-emitting structure. The heat exchange area between the first heat-dissipation module and the light-emitting structure can be larger, so that a better heat-dissipation effect can be achieved.

The foregoing are only some embodiments of the present disclosure and are not intended to limit the present disclosure, and any modifications, equivalent substitutions, improvements, etc., made within the spirit and principles of the present disclosure shall be included within the scope of protection of the present disclosure.

What is claimed is:

1. A semiconductor structure, comprising.
a substrate;
a light-emitting structure on the substrate, wherein the light-emitting structure comprises a first type semiconductor layer, an active layer and a second type semiconductor layer which are sequentially stacked on the substrate, and the first type semiconductor layer comprises a first portion not covered by the active layer; and
a first heat-dissipation module at the first portion.

2. The semiconductor structure according to claim 1, wherein in a direction parallel to the substrate and along a sidewall of the active layer, the first heat-dissipation module comprises first heat-dissipation sub-modules and second heat-dissipation sub-modules which are arranged alternately, and a conductive layer that connects the first heat-dissipation sub-modules and the second heat-dissipation sub-modules in series, wherein the first heat-dissipation sub-modules are made of P-type semiconductor thermoelectric materials, and the second heat-dissipation sub-modules are made of N-type semiconductor thermoelectric materials.

3. The semiconductor structure according to claim 2, wherein the conductive layer comprises:
first conductive structures disposed apart and second conductive structures disposed apart, wherein the first conductive structures are at a side of the first heat-dissipation sub-modules and the second heat-dissipation sub-modules facing the substrate, and the second conductive structures are at a side of the first heat-dissipation sub-modules and the second heat-dissipation sub-modules away from the substrate;
wherein the first heat-dissipation modules are formed by groups which are connected in series, and each of the groups comprises one of the first heat-dissipation sub-modules, one of the first conductive structures, one of the second heat-dissipation sub-modules and one of the second conductive structures which are connected in series.

4. The semiconductor structure according to claim 2, wherein the conductive layer comprises:
third conductive structures disposed apart and fourth conductive structures disposed apart, wherein the third conductive structures are at a side of the first heat-dissipation sub-modules and the second heat-dissipation sub-modules facing the active layer, and the fourth conductive structures are at a side of the first heat-dissipation sub-modules and the second heat-dissipation sub-modules away from the active layer;
wherein the first heat-dissipation modules are formed by groups which are connected in series, and each of the groups comprises one of the first heat-dissipation sub-modules, one of the third conductive structures, one of the second heat-dissipation sub-modules and one of the fourth conductive structures which are connected in series.

5. The semiconductor structure according to claim 4, wherein materials of the conductive layer are light reflective materials; and the third conductive structures and/or the fourth conductive structures form a grating.

6. The semiconductor structure according to claim 1, wherein the semiconductor structure further comprises:
a dielectric layer between the light-emitting structure and the first heat-dissipation module, so that the first heat-dissipation module is electrically isolated from the light-emitting structure.

7. The semiconductor structure according to claim 6, wherein the dielectric layer further covers a sidewall of the light-emitting structure and a surface of the light-emitting structure away from the substrate; and the semiconductor structure further comprises:
a first electrode electrically connected to the first type semiconductor layer through a first through-hole which is in the dielectric layer on the first portion; and
a second electrode electrically connected to the second type semiconductor layer through a second through-hole which is in the dielectric layer on the second type semiconductor layer.

8. The semiconductor structure according to claim 7, wherein in a direction parallel to the substrate, the first heat-dissipation module surrounds a circumference formed by the sidewalls of the active layer; or the first heat-dissipation module surrounds a part of the sidewalls of the active layer.

9. The semiconductor structure according to claim 8, wherein in the direction parallel to the substrate, the first heat-dissipation module surrounds a circumference formed by the sidewalls of the active layer, the first electrode is at a side of the first heat-dissipation module away from the active layer.

10. The semiconductor structure according to claim 8, wherein in the direction parallel to the substrate, the first heat-dissipation module surrounds a part of the sidewalls of the active layer, an orthogonal projection of the first heat-dissipation module on the substrate is an annulus with a gap, and at least a part of an orthogonal projection of the first electrode on the substrate is in the gap.

11. The semiconductor structure according to claim 6, wherein a material of the dielectric layer is an insulation material, and the dielectric layer comprises a DBR structure.

12. The semiconductor structure according to claim 1, wherein a surface of the first heat-dissipation module away from the substrate is higher than a surface of the active layer away from the substrate.

13. The semiconductor structure according to claim 1, wherein the semiconductor structure further comprises:
a second heat-dissipation module on a surface of the light-emitting structure away from the substrate.

14. The semiconductor structure according to claim 13, wherein in a direction parallel to the substrate, the second heat-dissipation module comprises:
third heat-dissipation sub-modules and fourth heat-dissipation sub-modules which are alternately arranged, the third heat-dissipation sub-modules are made of P-type semiconductor thermoelectric materials, the fourth heat-dissipation sub-modules are made of N-type semiconductor thermoelectric materials; and
fifth conductive structures disposed apart and sixth conductive structures disposed apart, wherein the fifth conductive structures are at a side of the third heat-dissipation sub-modules and the fourth heat-dissipation sub-modules facing the substrate, and the sixth conductive structures are at a side of the third heat-dissipation sub-modules and the fourth heat-dissipation sub-modules away from the substrate;
wherein the second heat-dissipation modules are formed by groups which are connected in series, and each of the groups comprises one of the third heat-dissipation sub-modules, one of the fifth conductive structures, one of the fourth heat-dissipation sub-modules and one of the sixth conductive structures which are connected in series.
